(19) United States
(12) Patent Application Publication
(10) Pub. No.: US 2007/0102822 A1
(43) Pub. Date: May 10, 2007

(54) Aluminum base target and process for producing the same

(76) Inventors: Takashi Kubota, Saitama (JP); Yoshinori Matsuura, Saitama (JP); Kazuteru Kato, Fukuoka (JP)

Correspondence Address: ROBERTS & ROBERTS, LLP;ATTORNEYS AT LAW, P.O. BOX 484, PRINCETON, NJ, 08542-0484, US

(21) Appl. No.: 10/570,619

(22) PCT Filed: Dec. 20, 2004
(86) PCT No.: PCT/JP04/19004

§ 371 Date: Nov. 1, 2006

(30) Foreign Application Priority Data
Dec. 18, 2003 (JP) 2003-421483

(51) Int. Cl. H01L 23/48

(52) U.S. Cl. 257/771

(57) ABSTRACT

An object of the present invention is to provide an aluminum-based target having a large area which has internal defects such as blow holes reduced to a minimum and has no warp. The aluminum-based target consisting of a plurality of aluminum alloy target members has a joint in which the aluminum alloy target members are joined with a friction stir welding method. The joint contains precipitates of an intermetallic compound with diameters of 10 μm or smaller dispersed in an aluminum matrix, and blow holes with diameters of 500 μm or less in an amount of 0.01 to 0.1/cm².

### TECHNICAL FIELD

The present invention relates to an aluminum-based target made of an aluminum alloy, and particularly relates to a large aluminum-based target having a large area.

### BACKGROUND ART

In recent years, a thin film of an aluminum alloy formed from an aluminum-based target has been used in forming wiring constituting a semiconductor device such as a thin film transistor in a liquid crystal display. The demand for this aluminum-based target is further increasing with the increased demand for electronic and electrical products in recent years. In an industry of manufacturing semiconductor devices, a technology of manufacturing at a time a large quantity of semiconductor devices having a very precise structure is remarkably progressing. Specifically, a technology is progressing which forms the thin film in a large area for forming wiring by sputtering a target having a very large area, and manufactures a large quantity of the semiconductor devices at a time.

Currently, in the field of manufacturing semiconductor devices, a target (the fourth generation) having the area of 1,150×980 mm is used for manufacturing them, but a target with the area as large as about 2,500×2,500 mm is planned to be used in future. In order to realize such a development of the technology for manufacturing the semiconductors, a large target with an extremely large area has to be indispensably provided.

In order to cope with the trend of upsizing (increasing the area of) the target, a method is employed which manufactures a wide target member, for instance, with a large-scale continuous casting apparatus or rolling mill, or joins a plurality of rolled target members so as to have predetermined thickness.

However, the use of a large-scale continuous casting apparatus and a rolling mill inevitably increases a facility cost, and it is difficult to manufacture various sorts of target materials having a desired composition.

On the other hand, in the case of manufacturing a target material having a large area by joining a plurality of target members having a small area, an electron beam welding technique is adopted which can weld a part to be joined by instantly melting the part (cf. Patent Document 1). The electron beam welding melts a part to be joined of a target member to frequently cause splash in alloys having some compositions, and tends to easily form voids called blow holes in a weld zone. When a target having a joint containing such blow holes is used for forming a thin film with a sputtering method, it causes unstable discharge during sputtering, and consequently may not form a stable thin film. In addition, the target joined through electron beam welding has a problem of easily causing a warp in a target itself affected by melting and solidification.

Furthermore, the thickness of a target tends to be increased with the upsizing of a target, but electron beam welding is anticipated to hardly cope with the tendency from the viewpoint of welding energy. In addition, the electron beam welding method needs a vacuum atmosphere during welding, which is not preferable for manufacturing a target with a large area, hardly reduces a manufacturing cost and hardly supplies an inexpensive upsized target.

### DISCLOSURE OF THE INVENTION

The present invention is designed with respect to the above described backdrop and is directed at providing a next-generation large target, particularly at inexpensively providing an aluminum-based target which has internal defects such as blow holes reduced to a minimum and has not warp, and a manufacturing method therefor.

As a result of intensive research for such a technology of joining a plurality of targets to manufacture a large target material for solving the above described problems, the present inventors have found a technology of inexpensively manufacturing the large aluminum-based target material having significantly few internal defects, and arrived at the present invention.

An aluminum-based target consisting of a plurality of aluminum alloy target members according to the present invention is characterized in that the target has a joint in which aluminum alloy target members have been joined with a friction stir welding method.

An aluminum-based target according to the present invention has extremely few internal defects, or equivalently, voids such as blow holes in the joint, and has little warp in itself because of having little distortion in the joint. In addition, the aluminum-based target with a large area according to the present invention can be manufactured with a comparatively inexpensive cost because of being joined with a friction stir welding method; can be inexpensively provided; can realize a thin film even with a large area having a uniform composition and thickness because of having few blow holes in the joint, and causes stable discharge during sputtering; and can be easily upsized because of being manufactured by joining target members in the air.

A friction stir welding method in the present invention joins materials in a solid-phase state. Specifically, the method joins target members by abutting the target members with each other, inserting a columnar body (a probe) called a star rod to the abutted part into a predetermined depth, and moving it along an abutting line while rotating it in the state.

An aluminum-based target according to the present invention has a structure having precipitates with diameters of 10 μm or smaller dispersed in the joint. A conventional electron beam welding method tends to cause segregation in a weld zone and to produce the weld zone having a composition different from that of a matrix, so that a thin film formed by sputtering such an electron-beam-welded target may cause a problem of uniformity of a thin film, or equivalently, of a nonuniform composition and thickness of the thin film. On the other hand, the joint in an aluminum-based target according to the present invention has a structure having precipitates with diameters of around 0.1 to 10 μm dispersed therein, which is almost equal to a structure of the aluminum matrix having precipitates such as intermetallic compounds and carbides dispersed therein, so that it can provide a highly uniform thin-film.

An aluminum-based target according to the present invention preferably employs an aluminum alloy comprising at least one or more elements selected from the group consisting of nickel, cobalt and iron, and the balance aluminum. The aluminum alloy may further include carbon, and still further silicon and neodymium. This is because an aluminum alloy including nickel, cobalt, iron, or silicon and neodymium provides a target member containing such dispersed precipitates as to impart the alloy preferred viscosity and create a suitable friction state for a star rod to rotate during friction stir welding. The contents of the nickel, cobalt, iron, or silicon and neodymium are preferably 0.1 to 10 at %, but particularly when the aluminum alloy contains at least one or more elements selected from the group consisting of nickel, cobalt and iron, the contents are preferably 0.5 to 7.0 at %. In addition, the content of silicon is preferably 0.5 to 2.0 at % or that of neodymium is preferably 0.1 to 3.0 at %. When carbon is contained in the target member, it precipitates as carbides which are assumed to show an effect of a lubricant. The content of carbon is preferably 0.1 to 3.0 at %. In addition, silicon and neodymium also forms precipitates which are assumed to work as the lubricant, as in the case of carbon. When the aluminum-based target contains silicon, it can effectively prevent silicon from diffusing into a formed thin film of the aluminum alloy. Furthermore, an aluminum alloy containing the above described elements provides an aluminum-based target which can form a thin film with superior film qualities such as heat resistance and low electric resistance.

An aluminum-based target produced by joining a plurality of aluminum alloy target members according to the present invention has a joint preferably containing blow holes with diameters of 500 μm or less of 0.01-0.1 holes/cm². Such a target having the joint with extremely few blow holes as in the present invention makes discharge in sputtering adequately stable, and makes a highly uniform thin-film stably formed. In addition, the joint preferably does not have blow holes with diameters exceeding 500 μm. An aluminum-based target having the joint with such few internal defects can realize more stable sputtering which hardly causes an arcing phenomenon and a splashing phenomenon.

The above described aluminum-based target according to the present invention can be manufactured by abutting the end faces of each one side of aluminum alloy target members, placing a probe for friction stir welding at an abutted part, generating a relative circulation movement between the probe and the abutted part, causing a plastic flow in the abutted part by a generated frictional heat, and joining the aluminum alloy target members.

The joining process is performed preferably from both faces of the front side and the back side of the aluminum alloy target member. The well-known shape of the aluminum-based target includes a rectangle-tabular shape, a disk shape and a cylindrical shape, but for any shape, the joining process is carried out preferably from the front side and the back side of the member.

A friction stir welding method according to the present invention causes extremely few internal defects and little distortion in a joint, so that it causes a warp in a target itself in comparison with a conventionally used electron beam welding method. Accordingly, in the case of joining a plurality of aluminum alloy target members of, for instance, rectangular plates into one target, the target can make the warp small by only abutting the end faces of each one side of the aluminum alloy target members of the rectangular plates and joining the formed abutted part from the one surface side (the front side of the aluminum alloy target member). If the formed joint only from the one surface side (the surface side of the aluminum alloy target members) is again joined from the opposite side (the back side of the aluminum alloy target members), the produced target can make the warp further small.

In a method for manufacturing an aluminum-based target according to the present invention, if target members are joined at a plurality of abutted parts, the adjacent abutted parts are preferably joined in the same moving direction of a probe from a starting point to an end point.

For instance, when a large aluminum-based target with a large area will be manufactured, generally, a plurality of aluminum alloy target members of rectangular plates are joined. Such a large aluminum-based target is preferably manufactured in the following way: placing a plurality of aluminum alloy target members of rectangular plates in parallel; forming two or more abutted parts in parallel by abutting end faces of each one side of the aluminum alloy target members of the rectangular plates; placing a columnar body (a probe) for friction stir welding at the abutted parts; joining the aluminum alloy target members by producing a plastic flow in the abutted parts with a produced frictional heat, while moving the probe from the start point to the end point at the abutted parts and forming a relative circulation movement between the probe and the abutted part; and joining the adjacent abutted parts in the same direction of the probe moving from the start point to the end point. Thus formed large aluminum-based target can make its warp extremely small. The reason is supposed to be that the influence of frictional heat in joints can be equalized from the start point side to the end point side at each abutted part.

Furthermore, in a method for manufacturing an aluminum-based target according to the present invention, it is preferable to move a probe in an opposite direction from a start point to an end point when joining adjacent abutted parts, if there are a plurality of the abutted parts.

As described above, when a large aluminum-based target is manufactured, for instance, by placing a plurality of aluminum alloy target members of rectangular plates in parallel, abutting the end faces of each one end of the aluminum alloy target members of the rectangular plates, and joining two or more abutted parts arranged in parallel, it is effective to move a probe in an opposite direction from each other, from the start point to the end point. In comparison with the method of moving a probe in the same direction as described above, the joining method of moving in the opposite direction can further decrease a warp in the formed large aluminum-based target, and thermal influence by a generated heat during joining.

In the above described method for manufacturing an aluminum-based target according to the present invention, a travel distance per revolution of a probe shall be preferably 0.5 to 1.4 mm during a joining step. The travel distance per revolution of a probe below 0.5 mm or over 1.4 mm tends to cause internal defects such as blow holes in a joint, and also cause nodules and particles.

In a method for manufacturing an aluminum-based target according to the present invention, a relative density of an aluminum alloy target member is preferably 95% or more. The relative density is the ratio of the actually measured density of a target with respect to the theoretical density of the target. When aluminum alloy target members with the low relative density are joined, the obtained target has a high possibility of causing many internal defects such as blow holes therein. When aluminum alloy target members with the relative density value of less than 95% are joined, the joint tends to have a different density from that in the other part, and can not realize adequate sputtering characteristics. Accordingly, the aluminum-based target formed by using the aluminum alloy target member having the relative density of 95% or more can control an arcing phenomenon and a splashing phenomenon, and provide adequate sputtering performance.

As described above, a joining method according to the present invention produces a large aluminum-based target which contains extremely few internal defects such as blow holes, is free from a warp, and consequently even when a large area of a thin film is formed with a sputtering technique, can realize a thin film with a highly uniform composition and thickness over a large area. In addition, the joining method according to the present invention is not so much restricted by the facility, so that it can inexpensively provide the large aluminum-based target of the next generation.

Best Mode for Carrying Out the Invention

A preferred embodiment of the present invention will be described below.

A first embodiment: in the first embodiment, aluminum-based targets of an aluminum-nickel-carbon alloy were manufactured with a friction stir welding method (Example 1) and an electron beam welding method (Comparative Example 1), and the characteristics were compared.

A target member used in present embodiment 1 was manufactured in the following way. At first, aluminum with the purity of 99.99% was charged into a carbon crucible (with the purity of 99.9%), was heated to the temperature range of 1,600 to 2,500° C., and was melted. The aluminum was melted in the carbon crucible in an argon gas atmosphere having atmosphere pressure. The aluminum was kept at the melting temperature for about 5 minutes to produce an aluminum-carbon alloy in the carbon crucible, and the molten metal was charged into a carbon mold, was left to be naturally cooled, and was cast therein.

The ingot of the aluminum-carbon alloy cast in the carbon mold was taken out, charged into a carbon crucible for remelting, together with each predetermined quantity of aluminum with the purity of 99.99% and nickel, heated to 800° C. to remelt them, and was stirred for about 1 minute. The remelting step was also performed in the atmosphere of argon gas at atmospheric pressure. After having been stirred, the molten metal was cast into a copper water-cooling mold to form a tabular ingot. The ingot was further rolled with a rolling mill to form a plurality of rectangle-tabular target members with the size of 10 mm thick, 400 mm wide and 600 mm long.

The side face of the target member was planed by milling and subjected to friction stir welding. The friction stir welding was performed in the state shown in FIG. 1(A). The side faces of two target members T were kept to be abutted, and the star rod 1 of a commercially available friction stir welding device was placed on the upper part of the abutted part. The cross-section schematic view of the used star rod 1 is shown in FIG. 1(B), and a tip 2 to be abutted with a target member had the diameter of [symbol] 10 mm (the unit of values described for each diameter in FIG. 1(B) is mm). A condition for operating the friction stir welding device was set to 500 rpm for the rotational speed of the tip 2 (made of steel) of the star rod 1 and 300 mm/min for the traveling speed (a traveling distance of 0.6 mm per revolution) of the tip. During the operation, the tip of the star rod was vertically abutted with the surface of a target member (a tilting angle of the tip at 0 degree).

For comparison, a target material was produced by planing side faces of two target members with a milling machine, and then welding them with an electron beam welding device (Comparative Example 1). The electron beam welding was carried out in the conditions of the accelerating voltage of 120 kV, the beam current of 18 mA and the welding speed of 10 mm/sec.

On thus obtained target material with the width of 800 mm and the length of 600 mm was subjected to examinations of observation of a joint with a SEM, observation of a metallographic structure, measurement on warping characteristics, observation of an eroded surface and measurement on discharge characteristics.

With an SEM, the cross section of a joint shown in FIG. 2 was observed. FIG. 2 shows a perspective view from the side face of a joint. The one part A of a target member T, the upper portion B and lower portion C of the joint were observed with the SEM (with the magnification of 1,000 times). In addition, for the target of Comparative Example 1, a boundary surface between a weld zone and a target member was observed with an SEM. The results of SEM observation of Example 1 are shown in FIGS. 3 to 5.

FIG. 3 is an observation result for a part A in FIG. 2, FIG. 4 for a part B in FIG. 2 and FIG. 5 for a part C in FIG. 2. As is clear from the figures, the sizes of Al₃Ni (parts shown like white spots in the photographs) which are the precipitates of an intermetallic compound, are not almost different between those of a target member T and a joint J. The precipitates (Al₃Ni) of the intermetallic compound had the diameters of 0.1 to 10 μm. In addition, an almost similar tendency was seen on the distribution of Al₄C₃ (10 to 100 μm) which is a carbide. On the other hand, FIG. 6 shows the observation result of the boundary in the weld zone of the target material welded by electron-beam-welding (Comparative Example 1). It was confirmed that the structure of the weld zone (a left side from the middle of a photograph) is greatly different from that of the target material in the vicinity of the weld zone (a right side from the middle of the photograph), or equivalently, that of a matrix.

In the next place, an observation method for a metallurgical structure of a joint J and the result will be described. A metallographic structure was observed on the surfaces of the upper side and side face of a target material with a metallographic microscope, after the joint shown in FIG. 2 had been etched with a cupric chloride solution for a predetermined period of time. The observation results for the structure are shown in FIGS. 7 and 8.

The structure of an upper surface is shown in FIG. 7, and the structure of a side surface in FIG. 8. As is shown in the observation results, the structures do not show significant difference between a target member side and a joint.

Then, a target material according to the present embodiment 1 was mounted on a horizontal plane, and a warping state was examined to prove that the target material had almost no warp. Through the above described structure observation and a visual observation of a joint, it was confirmed that a member does not have crack caused by friction stir welding.

Subsequently, the result of having observed an eroded state will be now described. The eroded state was observed by the following procedure: cutting out a target 11 of a disk (with the diameter of 203.2 mm and the thickness of 10 mm) from a target material 10 as shown in FIG. 9; mounting it on a commercially available sputtering apparatus (not shown); sputtering it with the electric power of the direct current of 4 kW for six hours; taking the target 11 out; and observing a part E from above, in which the target material was most deeply eroded by sputtering. The observation results for the eroded parts are shown in FIGS. 10 and 11.

FIG. 10 shows the result of Example 1 and FIG. 11 shows that of Comparative Example 1. According to an observation result for erosion in the target of the present Example 1, defects such as blow holes were not recognized in a joint. On the other hand, in the target of Comparative Example 1, there were many blow holes (defects of a white spot seen in a black weld zone in the center of the photograph). In addition, when the number of blow holes in the joint of the example was measured, no hole was recognized in a part corresponding to the area of about 9 cm². As a result of having had examined other eroded parts, it was known that there was not the blow hole with a larger diameter than 500 μm in the target of Example 1, and there were blow holes with diameters of 500 μm or less in the amount of about 0.06/cm². In addition, as a result of having had examined a plurality of target materials, it was known that blow holes with diameters of 500 μm or less existed in an amount of 0.01 to 0.1/cm² in the joint of the target material of Example 1. On the other hand, as a result of having had examined the same area with Example 1 in a weld zone of a target of Comparative Example 1, it was known that blow holes with diameters of 500 μm or less existed in the amount of 10/4.5 cm² (2.2/cm²). The amount of the blow holes in the above description was measured by observing an eroded part after having had been sputtered (with 12.3 W/cm² for 6 hours), with a metallographic microscope, so that the observable size for the blow hole was 1 μm or larger.

Furthermore, the results of having examined the state of generated arcing during sputtering will be now described. The state of generated arcing was examined by mounting the above described targets of Example 1 and Comparative Example 1 one by one on a commercially available sputtering apparatus (not shown); sputtering it with the charged power density of 12.3 W/cm² for a predetermined period of time; and counting the generated arcing (from voltage change) during sputtering. The results are shown in Table 1.

TABLE 1

| | | Comparative Example 1 | |
|---|---|---|---|
| | Sample 1 | Piercing welding | Both sides welding |
| Arcing occurrence | 3.4 | 20.4 | 12.0 |
| rate (the number of | | | |
| counts/min) | | | |

As shown in Table 1, the target of Example 1 did not show so many arcing phenomena, which proved that adequate sputtering could be performed with the target. On the other hand, any target of piercing welding and both sides welding in Comparative Example 1 showed a considerable number of arcing occurring during sputtering in comparison with Example 1. The above described piercing welding of Comparative Example 1 in Table 1 means that the target was welded in the above described electron beam welding condition only from one side, and both sides welding means that the target was welded in the above described electron beam welding condition from both sides.

Second Embodiment: here, results of having investigated conditions for friction stir welding of Example 1 in the above described first embodiment will be described. The investigated friction stir welding conditions are shown in Table 2. The other conditions were similar to Example 1.

TABLE 2

| | Rotation | Traveling | Traveling distance | Arcing |
|---|---|---|---|---|
| | speed | speed | per revolution | occurrence rate |
| Condition | rpm | mm/min | mm/rotation | count/min |
| 1 | 500 | 200 | 0.40 | 10.2 |
| 2 | 500 | 225 | 0.45 | 8.0 |
| 3 | 500 | 250 | 0.50 | 4.9 |
| 4 | 500 | 300 | 0.60 | 3.4 |
| 5 | 500 | 500 | 1.00 | 4.3 |
| 6 | 500 | 700 | 1.40 | 4.5 |
| 7 | 500 | 800 | 1.60 | 7.9 |
| 8 | 500 | 850 | 1.65 | 9.5 |

In addition, the suitability of friction stir welding conditions was evaluated through examining the number of generated arcing while targets joined each condition were sputtered. The results are shown in Table 2. As is clear from Table 2, when the rotation speed of a star rod was fixed and the traveling speed was changed, the joined samples at the traveling distances per revolution of 0.50 to 1.40 mm/revolution showed very few arcing occurrences. From the results, it was thought that among friction stir welding conditions, the relation between the rotation speed and traveling speed of the star rod is important, and a traveling distance per revolution shorter than 0.50 mm/revolution or longer than 1.40 mm/revolution tends to cause internal defects such as blow holes, and also cause nodules and particles.

Third Embodiment: in Third Example, the results of having investigated a joining method when a large target is manufactured by combining a plurality of target members, are described.

At first, results of having examined the warp of a manufactured aluminum-based target are described on the basis of the following Example 2 and Comparative Example 2.

Example 2 and Comparative Example 2 had the same composition and were manufactured and joined in the same method as Example 1 and Comparative Example 1 in the above described First Embodiment.(Examples 3 to 5 and Comparative Example 3 shown below were also similarly manufactured). The above described target member had the size of 10 mm thick, 300 mm wide and 1,200 mm long, and a large target was formed into the size of 600 mm wide and 1,200 mm long, by joining the long sides of the members.

Warp value of each obtained target of Example 2 and Comparative Example 2 was determined by mounting it on a horizontal surface plate, specifying a part showing a maximum gap between surfaces of the target and the surface plate, in a target edge, and measuring the length of the gap. The measurement for the warp was conducted twice: just after joining and after correction treatment. The results are shown in Table 3. The above described correction treatment corrects warp through mounting both ends of the target on ties with the top of a warped arc of the target directing upward and pressing the target from the upper part with the use of a cold-pressing machine.

TABLE 3

| | Warp (mm) of target | | |
|---|---|---|---|
| | After | | |
| | joining | After correction treatment | Observation of joint |
| Example 2 | 10 | 5 | No defect |
| Comparative | 20 | 5 | Partly cracked |
| Example 2 | | | |

As is shown in Table 3, the target of Example 2 was confirmed to have a significantly small warp. In addition, as a result of having had visually observed a joint with the use of magnifying lens, no defect was observed in Example 2, but small cracking was recognized in the weld zone of the target of Comparative Example 2.

Subsequently, the results of having investigated a joining procedure of a friction stir welding method will be described. Here, two joining procedures specifically shown in (A) and (B) in FIG. 12 were carried out for the joining procedures of a friction stir welding method as shown in FIG. 12.

A first procedure is a method of manufacturing a large target (Example 3) of 900 mm wide and 1,200 mm long, as is specifically shown in (A) in FIG. 12, by preparing three pieces of rectangular target members (10 mm thick, 300 mm wide and 1,200 mm long), abutting the long side of each member, and joining them. In contrast to this, a second procedure is a method of manufacturing a large target (Comparative Example 3) with the same size, by preparing four pieces of square target members (10 mm thick, 450 mm wide and 600 mm long), abutting them into the combination of two by two matrix as specifically shown in (B) in FIG. 12, and joining them. They were joined in the same conditions as those shown in the first embodiment. In Example 3, the target members were joined by moving a star rod in the same direction as shown in an arrow of FIG. 12 (A). At first, target members T1 and T2 were joined and then T3 was abutted and joined to T2. On the other hand, in Comparative Example 3, at first, target members T1 and T2, and target members T3 and T4 were joined by moving star rods in the direction of an arrow, and then two rectangular members (T1-T2, T3-T4) were abutted and joined by moving the star rod in the direction of the arrow shown in the figure. In Example 3 and Comparative Example 3, the target members were joined by friction stir welding only from one side. The results of having measured the warps of the targets produced through changing joining procedures are shown in Table 4.

TABLE 4

| | Warp (mm) of target | |
|---|---|---|
| | After joining | After correction treatment |
| Example 3 | 13 | 10 |
| Comparative Example 3 | 15 | 12 |

The measurement of a warp and the correction treatment shown in Table 4 were performed in the same way as in Table 3. As is clear from Table 4, a joining procedure in Example 3 showed a smaller warp. In addition, the joined target of Comparative Example 3 needed to be corrected twice, specifically by correcting joined rectangular members T1 and T2, and T3 and T4 at first, and then correcting a large target formed by joining the two corrected members. In contrast to this, a large target formed with the procedure of Example 3 was sufficiently corrected with one-time treatment.

Subsequently, the results of having investigated a moving direction of a star rod in friction stir welding will be described. Here, a large target of 900 mm wide and 1,200 mm long was produced by arranging three pieces of rectangular target members (10 mm thick, 300 mm wide and 1,200 mm long) shown in (A) in FIG. 12 in parallel, and joining them. As for the moving direction of a star rod, as is shown in (C) in FIG. 13, two abutted parts were joined in the same directions (same as FIG. 12(A)) in one case (Example 4), and as is shown in FIG. 13(D), the abutted parts Ti and T2 and the abutted parts T2 and T3 were joined so that the star rod can move in an opposite direction from the other, in the other case (Example 5). The results of having measured the warps of Examples 4 and 5 are shown in Table 5. In the above description, Examples 4 and 5 were joined only from one side by friction stir welding.

TABLE 5

Warp (mm) of target

| | After joining | After correction treatment |
|---|---|---|
| Example 4 | 13 | 10 |
| Example 5 | 10 | 8 |

As is shown in Table 5, it was found that when producing a large target having the same shape, the case of the opposite moving direction of a star rod formed a smaller warp than the case of the same moving direction.

Furthermore, the results of having investigated the difference between joining methods from both sides and from one side will be described. Here, targets were prepared each by joining the abutted part between two target members (10 mm thick, 300 mm wide and 1,200 mm long) only from one side (a front side) as shown in FIG. 2, in one case (Example 6), and from both sides (a front side and a back side) in the other case (Example 7); and the warps were measured. The result is shown in Table 6.

TABLE 6

Warp (mm) of target

| | After joining | After correction treatment |
|---|---|---|
| Example 6 | 10 | 5 |
| Example 7 | 8 | 5 |

From the result in Table 6, it was discovered that joining from both sides gave a smaller warp of a target. In addition, a target joined from both sides could be easily corrected, because the warp itself after having had been joined was small.

Fourth Embodiment: in Fourth Embodiment, results of having investigated the influence of difference between methods for manufacturing a target member, on characteristics of a target joined by friction stir welding will be described.

In Fourth Embodiment, six pairs of target members (8 mm thick, 152.4 mm wide and 508 mm long) were each prepared through six manufacturing methods described below, and were each joined from only one side (in the same condition as in the above described embodiment 1) to form targets. The compositions of the used target members for the above target were three types of Al-3 at % Ni-0.3 at % C-2 at % Si, Al-2 at % Ti and Al-2 at % Nd.

Melting method: target members having the composition of Al-3 at % Ni-0.3 at % C-2 at % Si were manufactured in the same procedure as was described in Embodiment 1, and were joined. Target members with the compositions of Al-2 at % Ti and Al-2 at % Nd were manufactured similarly to Example 1 except for melting a material in a vacuum.

Hot-pressing method: target members were prepared by filling a carbon die having the size of 157.4 mm×513.0 mm×10 mm, with a mixture powder consisting of Al powder, Ni powder, C powder, Si powder, Ti powder and Nd powder, which had been appropriately mixed so as to have a predetermined composition; hot-pressing it in an Ar atmosphere with a pressure of 200 kg/cm² at 575° C. for one hour; and then machining the pressed powder into a predetermined shape.

Hot isostatic press molding method: target members were prepared through filling a die for HIP having the size of 157.4 mm×513.0 mm×10 mm, with a mixture powder consisting of Al powder, Ni powder, C powder, Si powder, Ti powder and Nd powder, which had been appropriately mixed so as to have a predetermined composition; hot-isostatic-pressing it in an atmosphere with a pressure of 1,000 kg/cm² at 575° C. for one hour; and then machining the pressed powder into a predetermined shape.

Cold isostatic press molding method: target members were prepared by filling a die for CIP having the size of 157.4 mm×513.0 mm×10 mm, with a mixture powder consisting of Al powder, Ni powder, C powder, Si powder, Ti powder and Nd powder, which had been appropriately mixed so as to have a predetermined composition; cold-isostatic-pressing it in an atmosphere with a pressure of 1,000 kg/cm² at room temperature for one hour; and then machining the pressed powder into a predetermined shape.

Pressing method: target members were prepared by filling a die having the size of 157.4 mm×513.0 mm×10 mm, with a mixture powder consisting of Al powder, Ni powder, C powder, Si powder, Ti powder and Nd powder, which had been appropriately mixed so as to have a predetermined composition; pressing it in an atmosphere with a pressure of 1,000 kg/cm² at room temperature for five minutes; and then machining the pressed powder into a predetermined shape.

Pressing-hot isostatic pressing molding method: this manufacturing method is constituted by the combination of the above described pressing with the hot isostatic pressing molding method to manufacture a target member. Specifically, target members were prepared by filling a die having the size of 157.4 mm×513.0 mm×10 mm, with a mixture powder consisting of Al powder, Ni powder, C powder, Si powder, Ti powder and Nd powder, which had been appropriately mixed so as to have a predetermined composition; pressing it in an atmosphere with a pressure of 1,000 kg/cm2 at room temperature for five minutes; subsequently, hot-isostatic-pressing it in an atmosphere with a pressure of 1,000 kg/cm² at 575° C. for one hour; and then machining the pressed powder into a predetermined shape.

Table 7 shows the evaluation results of the appearance and sputtering properties of six targets produced through joining target members obtained with the above described six manufacturing methods in the same condition as in Example 1. In addition, the relative density of each target shown in Table 6 is defined as a percentage of actually measured density to theoretical density ρ (g/cm³) calculated in the following expression, specifically, means the ratio (%) of actually measured density of an actually obtained sputtering target expressed in weight/volume to theoretical density. Accordingly, nearer to 100% is the relative density, the less internal holes such as blow holes contains the material and denser is the material.

TABLE 7
Method for
manufacturing

| target | Evaluation result | | |
|---|---|---|---|
| member | Al—3Ni—0.3C—2Si | Al—2Ti | Al—2Nd |
| Melting method | ⊚ (99.99%) | ⊚ (99.99%) | ⊚ (99.99%) |
| Hot-pressing | ◯ (95.1%) | ◯ (95.5%) | ◯ (94.5%) |
| method | | | |
| Hot isostatic press | ⊚ (99.8%) | ⊚ (99.7%) | ⊚ (99.8%) |
| molding method | | | |
| Cold isostatic press | X (78.3%) | X (79.3%) | X (78.7%) |
| molding method | | | |
| Pressing method | X (74.8%) | X (76.3%) | X (75.4%) |
| Pressing-cold | ⊚ (99.9%) | ⊚ (99.8%) | ⊚ (99.9%) |
| isostatic | | | |
| pressing molding | | | |
| method | | | |

Values in the parentheses are relative density.

$$ρ ≡ ( \frac{{C}_{1} / 100}{{ρ}_{1}} + \frac{{C}_{2} / 100}{{ρ}_{2}} + ⋯ + \frac{{C}_{i} / 100}{{ρ}_{i}} ) \qquad [ Formula 1 ]$$

C₁, C₂ to Cᵢ represent the contents of elements in the composition (w %)

In evaluation results shown in Table 7, “⊚” means that the target gave significantly adequate sputtering properties and showed no problem in a joint, “∘” means that a target gave adequate sputtering properties and did not show a special problem in a joint, and “x” means that a target had defects and the unevenness of density in a joint and moreover showed unfavorable sputtering properties.

From the result in Table 7, it was known that by using target members manufactured by a cold isostatic pressing molding method or a simple pressing method, an adequate target could not be manufactured even by a friction stir welding method. Finally, it was found that an aluminum-based target produced by using target members having high relative density, and joining them with a friction stir welding method can realize adequate sputtering properties while inhibiting an arcing phenomenon and a splashing phenomenon.

### BRIEF DESCRIPTION OF THE DRAWINGS

FIG. 1 shows a schematic view (A) depicting a state of friction stir welding, and a cross-sectional schematic view (B) of a star rod;

FIG. 2 is a schematic perspective view showing the cross section of a joint;

FIG. 3 is an SEM observation photograph of a joint in Example 1;

FIG. 4 is an SEM observation photograph of a joint in Example 1;

FIG. 5 is an SEM observation photograph of a joint in Example 1;

FIG. 6 is an SEM observation photograph of a weld zone in Comparative Example 1;

FIG. 7 is an observation photograph of a structure in a joint;

FIG. 8 is an observation photograph of a structure in a joint;

FIG. 9 is a schematic perspective view of a target material;

FIG. 10 is an observation photograph of an eroded part in Example 1;

FIG. 11 is an observation photograph of an eroded part in Comparative Example 1;

FIG. 12 is a schematic perspective view showing joining procedures; and

FIG. 13 is a schematic perspective view showing a moving direction of a star rod during joining.

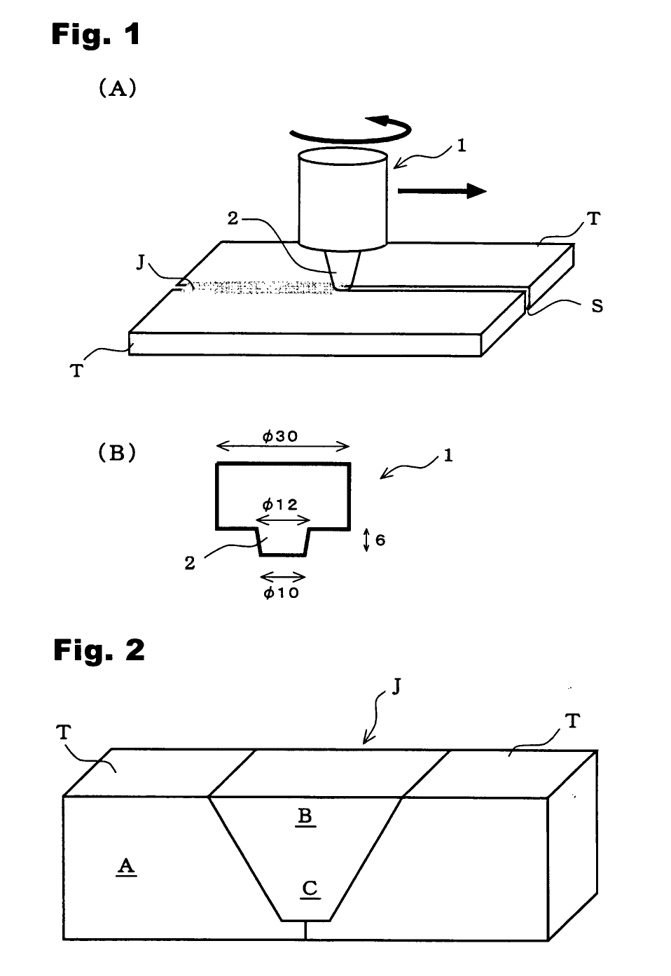

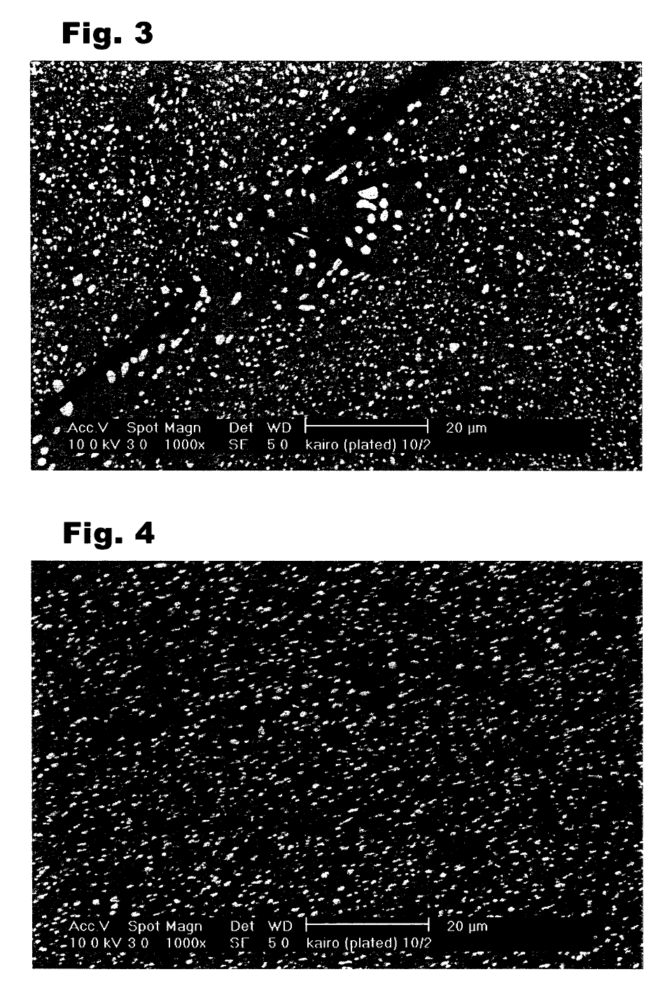

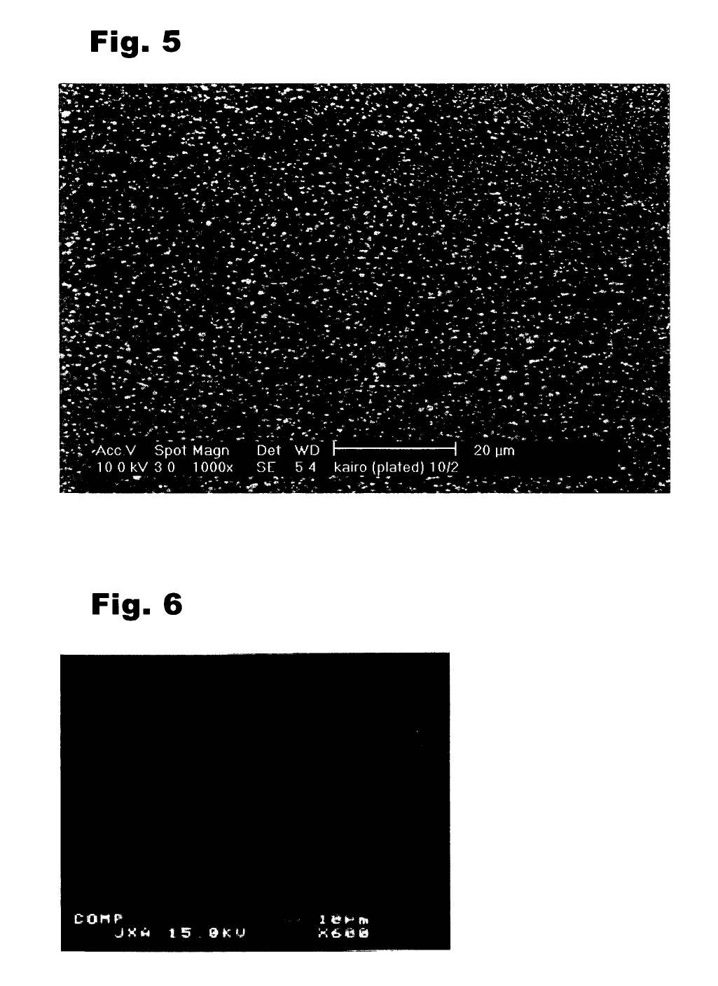

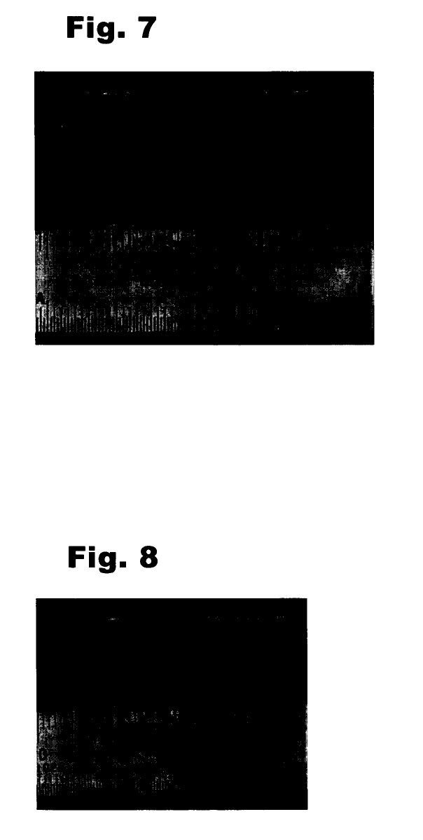

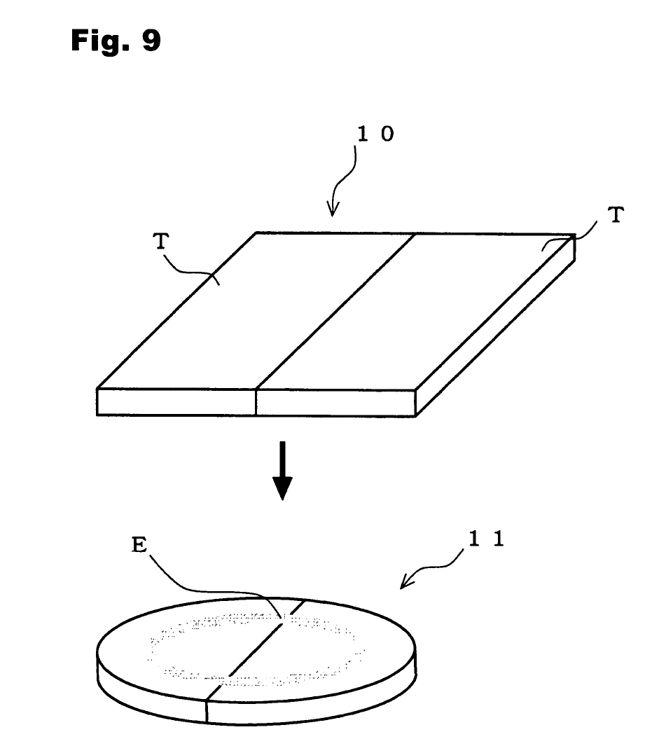

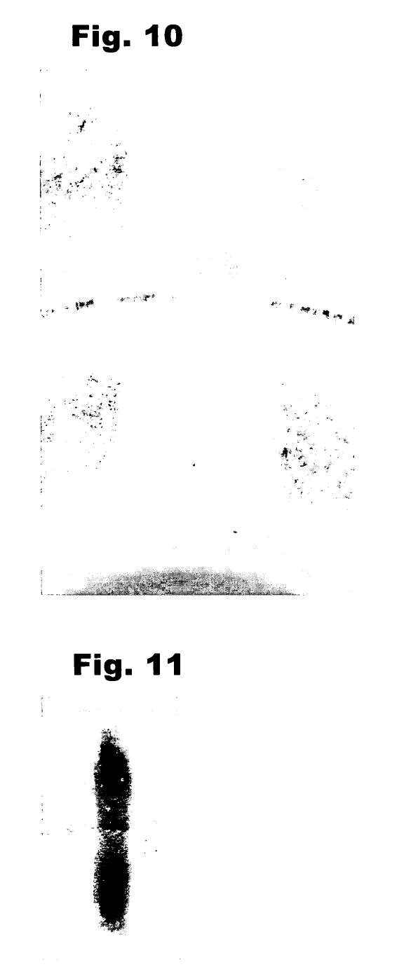

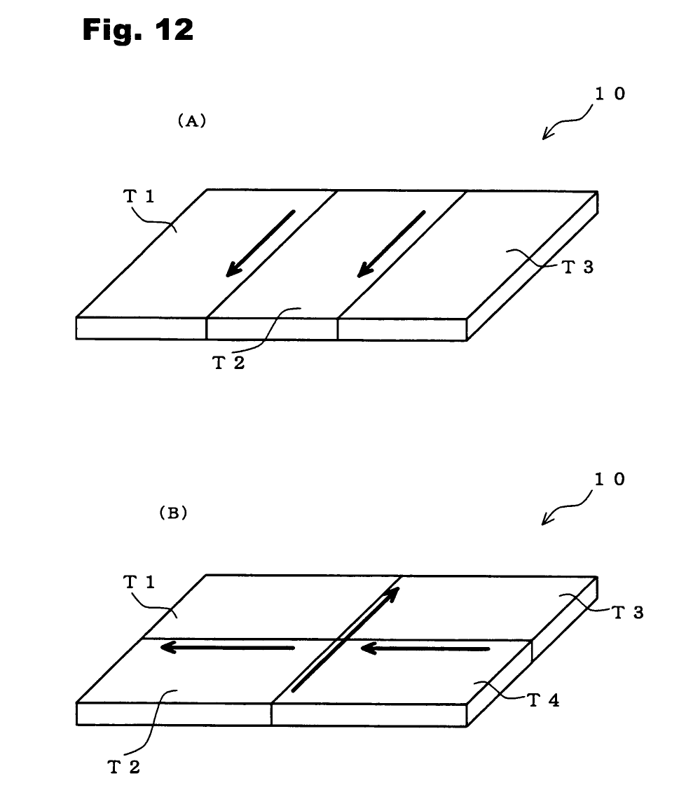

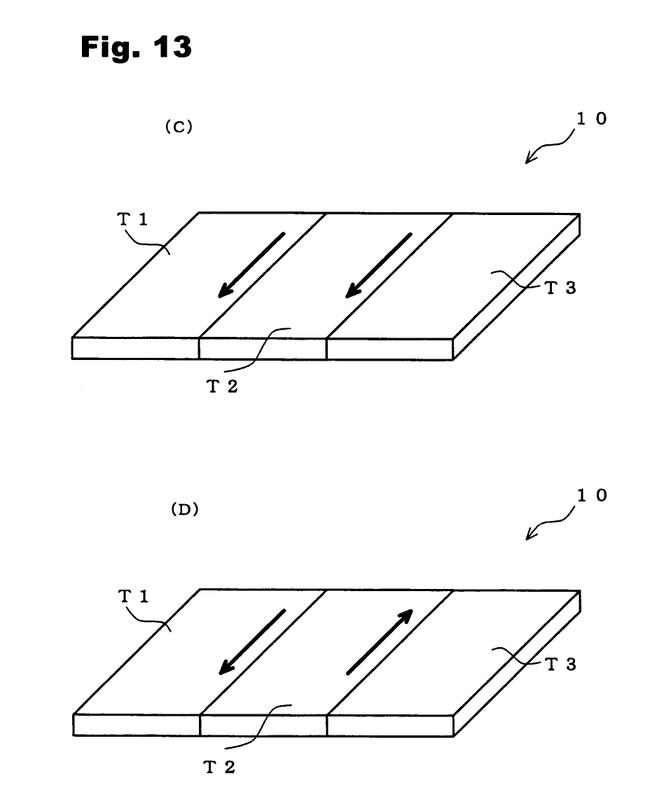

In the claims:

1. An aluminum-based target comprising a plurality of aluminum alloy target members which are joined at a joint in which the aluminum alloy target members have been joined with a friction stir welding method.

2. The aluminum-based target according to claim 1, wherein the joint includes dispersed precipitates with diameters of 10 μm or smaller.

3. The aluminum-based target according to claim 1, wherein the aluminum alloy comprises at least 0.5-7.0 at % of one or more elements selected from the group consisting of nickel, cobalt and iron, and the balance aluminum.

4. The aluminum-based target according to claim 3, wherein the aluminum alloy further includes 0.1 to 3.0 at % carbon.

5. The aluminum-based target according to claim 3, wherein the aluminum alloy further includes 0.5 to 2.0 at % silicon.

6. The aluminum-based target according to claim 3, wherein the aluminum alloy further includes 0.1 to 3.0 at % neodymium.

7. An aluminum-based target made by joining a plurality of aluminum alloy target members with each other at a joint wherein the joint has blow holes with diameters of 500 μm or smaller in an amount of 0.01-0.1 hole/cm².

8. An aluminum-based target made through joining a plurality of aluminum alloy target members with each other at a joint wherein the joint does not have blow holes with diameters exceeding 500 μm.

9. The aluminum-based target according to claim 7, wherein the joint contains dispersed precipitates with diameters of 10 μm or smaller.

10. The aluminum-based target according to claim 7, wherein the aluminum alloy comprises at least 0.5-7.0 at % of one or more elements selected from the group consisting of nickel, cobalt and iron, and the balance aluminum.

11. The aluminum-based target according to claim 7, wherein the joint is formed with a friction stir welding method.

12. A method for manufacturing an aluminum-based target which comprises the steps of:
abutting end parts of one side of aluminum alloy target members with each other; and
arranging a probe for friction stir welding at an abutted part to cause relative circulation movement between the probe and the abutted part, and producing a plastic flow in the abutted part by a generated frictional heat, and joining the aluminum alloy target members.

13. The method for manufacturing an aluminum-based target according to claim 12, wherein the aluminum alloy target members are joined from both sides of front side and back side of the aluminum alloy target members.

14. The method for manufacturing an aluminum-based target according to claim 12, wherein adjacent abutted parts are joined in the same moving direction of a probe from a start point to an end point.

15. The method for manufacturing an aluminum-based target according to claim 12, wherein the adjacent abutted parts are joined in the opposite moving direction of a probe from the other, from a start point to an end point.

16. The method for manufacturing an aluminum-based target according to claim 12, wherein a traveling distance per revolution of the probe is 0.5 to 1.4 mm.

17. The method for manufacturing an aluminum-based target according to claim 12, wherein the relative density of the aluminum alloy target member is 95% or higher.

18. An The aluminum-based target obtained through the method according to claim 12.

19. The aluminum-based target according to claim 8, wherein the joint contains dispersed precipitates with diameters of 10 μm or smaller.

20. The aluminum-based target according to claim 8, wherein the aluminum alloy comprises at least 0.5-7.0 at % of one or more elements selected from the group consisting of nickel, cobalt and iron, and the balance aluminum.
